(19) United States
(12) Patent Application Publication
(10) Pub. No.: US 2015/0194494 A1
(43) Pub. Date: Jul. 9, 2015

(54) FIELD-EFFECT TRANSISTOR FOR HIGH VOLTAGE DRIVING AND MANUFACTURING METHOD THEREOF

(71) Applicant: Electronics and Telecommunications Research Institute, Daejeon (KR)

(72) Inventors: Ho Kyun AHN, Daejeon (KR); Hae Cheon KIM, Daejeon (KR); Zin Sig KIM, Daejeon (KR); Sang Heung LEE, Daejeon (KR); Byoung Gue MIN, Sejong (KR); Hyung Sup YOON, Daejeon (KR); Dong Min KANG, Daejeon (KR); Seong Il KIM, Daejeon (KR); Jong Min LEE, Daejeon (KR); Jong Won LIM, Daejeon (KR); Yong Hwan KWON, Daejeon (KR); Eun Soo NAM, Daejeon (KR)

(73) Assignee: Electronics and Telecommunications Research Institute, Daejeon (KR)

(21) Appl. No.: 14/243,322

(22) Filed: Apr. 2, 2014

(30) Foreign Application Priority Data
Jan. 9, 2014 (KR) 10-2014-0002967

(51) Int. Cl. H01L 29/40; H01L 29/66; H01L 21/28; H01L 21/283; H01L 29/78; H01L 29/423

(52) U.S. Cl. CPC H01L 29/402; H01L 29/78; H01L 29/42356; H01L 21/28008; H01L 21/283; H01L 29/66477

(57) ABSTRACT

Disclosed are a field effect transistor for high voltage driving including a gate electrode structure in which a gate head extended in a direction of a drain is supported by a field plate embedded under a region of the gate head so as to achieve high voltage driving, and a manufacturing method thereof. Accordingly, the gate head extended in the direction of the drain is supported by the field plate electrically spaced by using an insulating layer, so that it is possible to stably manufacture a gate electrode including the extended gate head, and gate resistance is decreased by the gate head extended in the direction of the drain and an electric field peak value between the gate and the drain is decreased by the gate electrode including the gate head extended in the direction of the drain and the field plate proximate to the gate, thereby achieving an effect in that a breakdown voltage of a device is increased.

### CROSS-REFERENCE TO RELATED APPLICATIONS

This application is based on and claims priority from Korean Patent Application No. 10-2014-0002967, filed on Jan. 9, 2014, with the Korean Intellectual Property Office, the disclosure of which is incorporated herein in its entirety by reference.

### BACKGROUND

1. Field

The present invention relates to a field effect transistor for high voltage driving and a manufacturing method thereof. More particularly, the present invention relates to a field effect transistor for high voltage driving including a gate electrode structure in which a gate head extended in a direction of a drain is supported by a field plate embedded under a region of the gate head so as to achieve high voltage driving, and a manufacturing method thereof.

2. Discussion of Related Art

In general, a field effect transistor is manufactured by a process illustrated in FIGS. 1A to 1H.

First, as illustrated in FIG. 1A, an active layer 11 and a cap layer 12 are sequentially formed on a semiconductor substrate 10.

Next, as illustrated in FIG. 1B, a region in which source and drain electrodes are to be formed is defined by a photoresist pattern, a metal for an electrode is deposited, and then source and drain electrodes 13 are formed by Rapid Thermal Annealing (RTA) and the like.

Next, as illustrated in FIG. 1C, a multilayered photoresist layers 14a, 14b, and 14c are applied on the substrate on which the source and drain electrodes are deposited, and a T-shaped gate pattern 15a is formed by using photolithography, electron beam lithography, or the like.

Subsequently, as illustrated in FIG. 1D, a gate recess region 15b on which a gate metal is to be deposited is formed by performing a gate recess process of etching the semiconductor substrate exposed on the T-shaped gate pattern.

Next, as illustrated in 1E, a gate metal is deposited on the pattern, and the photoresist layer is removed by a lift-off process, to form a T-shaped gate electrode 16. Subsequently, as illustrated in FIG. 1F, an insulating layer 17 is deposited after the gate electrode is manufactured, and as illustrated in FIG. 1G, a lithography process for forming a field plate is performed.

As illustrated in FIG. 1H, a metal is deposited on the lithography pattern for forming the field plate, and then a photoresist layer is removed by performing a lift-off process to form the field plate 19.

The aforementioned transistor manufacturing method in the related art relates to a method of manufacturing a field effect transistor, and in a case where a gate head extended in a direction of a drain is manufactured, a region of the extended gate head becomes larger than a region of a gate foot, so that a phenomenon in which the region of the gate head is collapsed may occur, and thus reliability and uniformity of a device may deteriorate. Accordingly, there is a limitation in increasing the region of the gate head, and a separate field effect needs to be manufactured through a separate mask pattern, a lithography process, a metal depositing process, and the like. However, an electric field peak value between the gate and the drain is decreased at an edge of the gate in the direction of the drain by extending the region of the gate head, so that there is a limitation in improving a breakdown voltage. Accordingly, there is a problem in that it is impossible to sufficiently improve a high voltage driving characteristic of a nitride-based field effect transistor and a field effect transistor formed of other materials.

### SUMMARY

The present invention has been made in an effort to provide a field effect transistor which has no possibility of a collapse phenomenon of a gate electrode of which a gate head is extended, is capable of improving reliability and process uniformity, and is capable of improving a characteristic of a device so as to achieve high voltage driving of a device in manufacturing a field effect transistor including the gate electrode of which a region of the gate head is extended in a direction of the drain, and a manufacturing method thereof.

An exemplary embodiment of the present invention provides a field effect transistor, including: an active layer; a first insulating layer formed on the active layer; source and drain electrodes which are in contact with the active layer while passing through the first insulating layer; a field plate formed on the first insulating layer and positioned between the source and drain electrodes; a second insulating layer formed on the first insulating layer so as to cover the source and drain electrodes and the field plate; and a gate electrode including a gate foot passing through the first insulating layer and the second insulating layer, and a gate head formed on the second insulating layer and extended in a direction of the drain to be supported by the field plate.

Another exemplary embodiment of the present invention provides a method of manufacturing a field effect transistor, including: forming a first insulating layer and source and drain electrodes on an active layer, wherein the source and drain electrodes are in contact with the active layer while passing through the first insulating layer; forming a field plate on the first insulating layer; forming a second insulating layer on the first insulating layer on which the field plate is formed; forming a micro opening by etching the first insulating layer and the second insulating layer; and forming a gate electrode including a gate foot formed in the micro opening and a gate head formed on the second insulating layer, extended in a direction of the drain, and supported by the field plate.

According to the embodiment of the present invention, the gate head extended in the direction of the drain is supported by the field plate electrically spaced by using the insulating layer, so that it is possible to stably manufacture the gate electrode including the extended gate head, and gate resistance is decreased by the gate head extended in the direction of the drain and an electric field peak value between the gate and the drain is decreased by the gate electrode including the gate head extended in the direction of the drain and the field plate proximate to the gate, thereby achieving an effect in that a breakdown voltage of the device is increased. Further, a separate additional mask is not required while manufacturing a field plate, thereby improving productivity, achieving a more uniform process than an existing process, and reproducibly manufacturing transistors having excellent performance

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The above and other features and advantages of the present invention will become more apparent to those of ordinary skill in the art by describing in detail embodiments thereof with reference to the attached drawings in which:

FIGS. 1A to 1H are cross-sectional views illustrating a manufacturing process of a field effect transistor in the related art;

FIGS. 2 and 3 are cross-sectional views illustrating a structure of a field effect transistor according to an exemplary embodiment of the present invention;

FIGS. 4A to 4L are cross sectional views illustrating a manufacturing process of the field effect transistor according to the exemplary embodiment of the present invention; and

FIGS. 5 and 6 are graphs illustrating a characteristic of the field effect transistor according to the exemplary embodiment of the present invention.

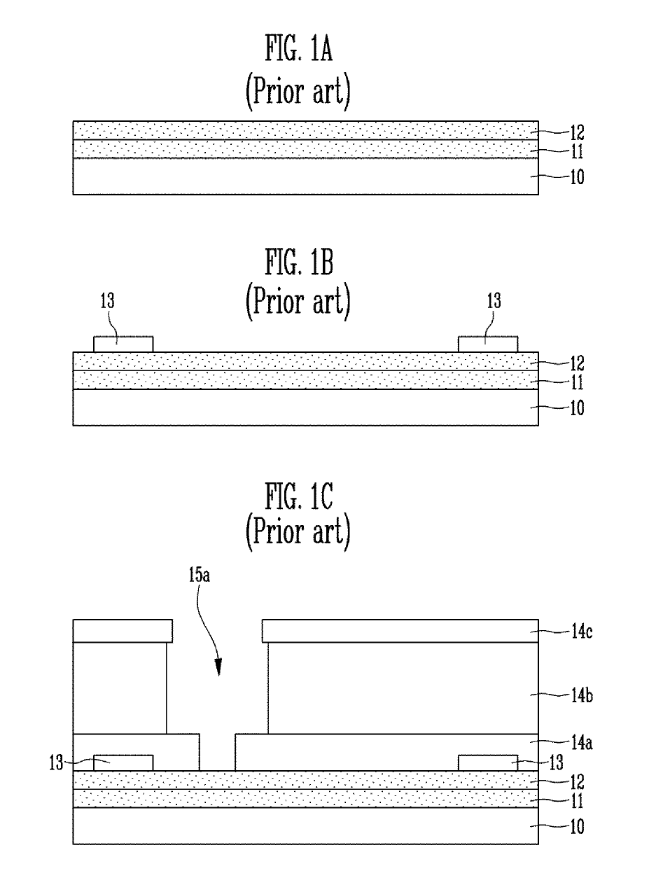

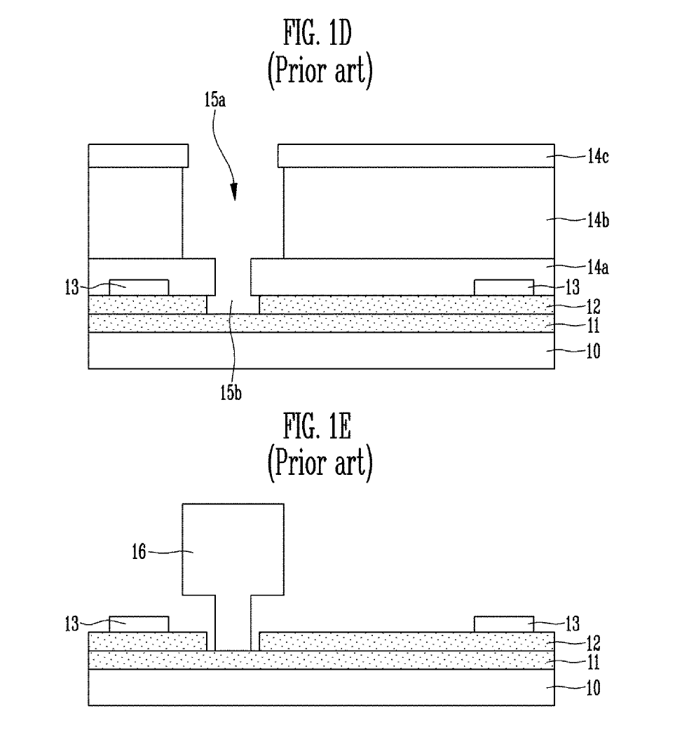

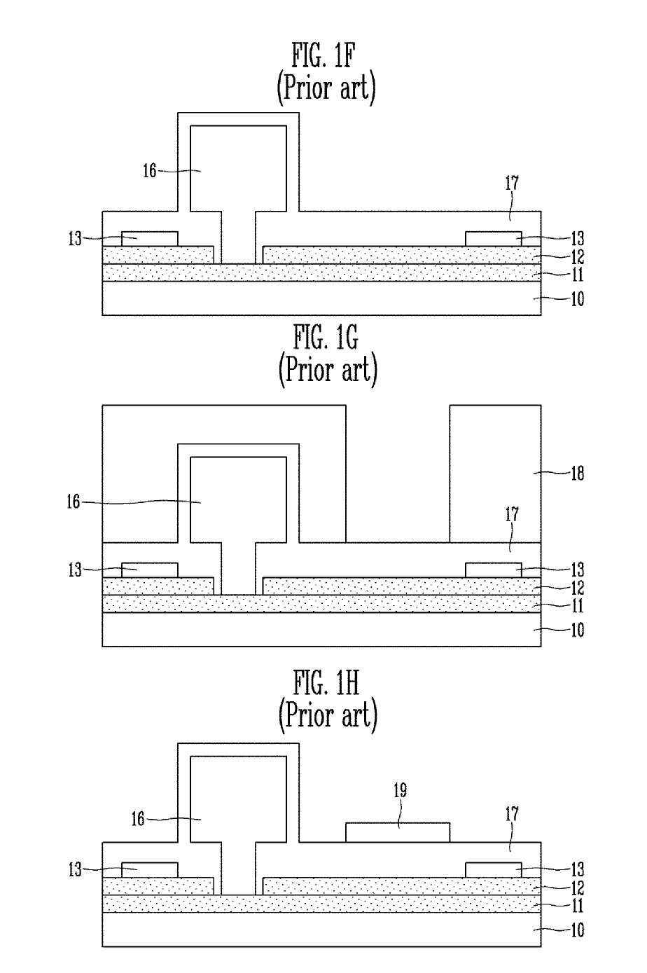

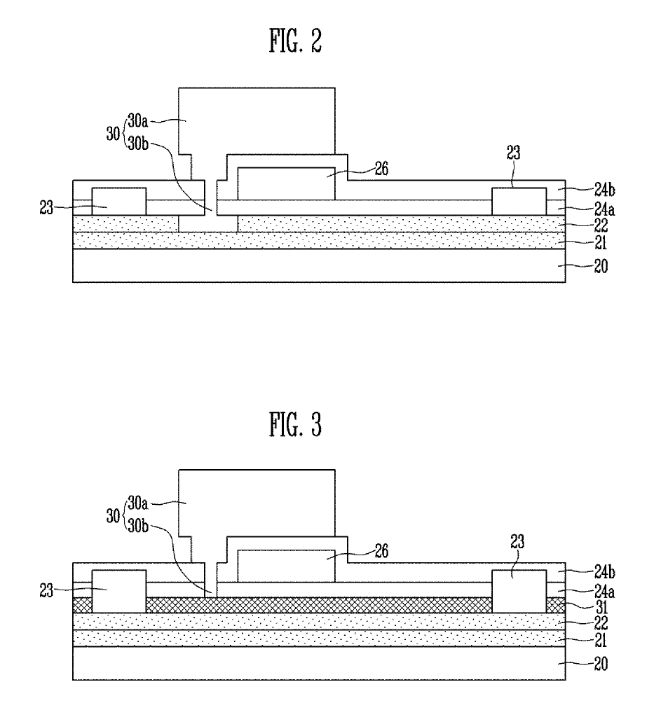

### DETAILED DESCRIPTION

Hereinafter, the most preferable embodiment of the present invention will be described. In the drawings, the thicknesses and the intervals of elements are exaggerated for convenience of illustration, and may be exaggerated compared to an actual physical thickness. In describing the present invention, a publicly known configuration irrelevant to the principal point of the present invention may be omitted. It should note that in giving reference numerals to elements of each drawing, like reference numerals refer to like elements even though like elements are shown in different drawings.

FIGS. 2 and 3 are cross-sectional views illustrating a field effect transistor according to an exemplary embodiment of the present invention.

Referring to FIGS. 2 and 3, a field effect transistor according to the present invention includes an active layer 21, a first insulating layer 24a formed on the active layer 21, source and drain electrodes 23 passing through the first insulating layer 24a to be in contact with the active layer 21, a field plate 26 formed on the first insulating layer 24a and positioned between the source and drain electrodes 23, a second insulating layer 24b formed on the first insulating layer 24a so as to cover the source and drain electrodes 23 and the field plate 26, and a gate electrode including a gate foot 30b passing through the first insulating layer 24a and the second insulating layer 24b, and a gate head 30a formed on the second insulating layer 24b and extended in a direction of the drain to be supported by the field plate 26. Further, the field effect transistor according to the present invention may further include a gate dielectric layer 31 interposed between a gate electrode 30 and the active layer 21 or between the gate electrode 30 and a cap layer 22.

The field effect transistor may further include a semiconductor substrate 20 positioned under the active layer 21 and the cap layer 22 positioned on the active layer 21. For example, before the source and drain electrodes 23, the active layer 21 and the cap layer 22 are sequentially formed on the substrate 20. A compound semiconductor, such as gallium nitride (GaN), silicon (Si), silicon carbide (SiC), or semi-insulating gallium arsenide (GaAs), or other semiconductor substrate may be used as the substrate 20, but the substrate 20 is not limited thereto. For example, in the case where the field effect transistor is a High Electron Mobility Transistor (HEMT) device using a hetero-junction of aluminum gallium nitride (AlGaN) and gallium nitride (GaN), the active layer 21 may be formed of a gallium nitride buffer layer and an aluminum gallium nitride barrier layer, and the cap layer 22 may be formed of a gallium nitride (GaN) layer.

Source and drain electrodes generally known in this art may be used as the source and drain electrodes 23, and for example, in a case where the field effect transistor is an HEMT device using a gallium nitride (GaN)-based compound semiconductor, a metal layer, in which Ti/Al/Ni/Au layers having predetermined thicknesses are sequentially deposited, may be used as the source and drain electrodes 23. For example, the source and drain electrodes 23 may be metal layers in which a titanium (Ti) layer having a thickness of 15 to 50 nm, an aluminum (Al) layer having a thickness of 50 to 150 nm, a nickel (Ni) layer having a thickness of 15 to 50 nm, and a gold (Au) layer having a thickness of 50 to 150 nm are stacked. Further, in a case where the field effect transistor is a device using a gallium arsenide (GaAs)-based compound semiconductor, such as an HEMT and a Metal Semi-conductor Field Effect

Transistor (MESFET), a metal layer in which an AuGe layer, a Ni layer, and an Au layer having predetermined thicknesses are sequentially deposited may be used as the source and drain electrodes 23. For example, the source and drain electrodes 23 may be a metal layer in which a gold-germanium (AuGe) layer having a thickness of 50 to 200 nm, a nickel (Ni) layer having a thickness of 30 to 60 nm, and a gold (Au) layer having a thickness of 50 to 150 nm are stacked.

The first insulating layer 24a may be deposited in a single layer or a multilayer, and may be formed of a material general in this field, for example, materials such as silicon nitride, silicon oxide, Al₂O₃, HfO₂, benzocyclobutene (BCB), and other porous silica thin layer, and the first insulating layer 24a serves to protect a surface of a compound semiconductor substrate. A thickness of the first insulating layer 24a may be selected within a range from 5 to 100 nm according to a process condition.

The field plate 26 formed in a predetermined region which is to correspond to a region of the gate head of the gate electrode between the source and drain electrodes may be formed by depositing a metal for the field plate, and a metal generally known in this art may be used as the metal for the field plate. For example, a multilayered metal layer, such as titanium (Ti)/gold (Au) and nickel (Ni)/gold (Au), may be used as the field plate 26. Further, the field plate 26 may be connected with the gate electrode 30 or the source electrode 23.

The second insulating layer 24b deposited on the substrate so that the field plate is electrically insulated within the active region may be deposited in a single layer or a multilayer similar to the first insulating layer 24a, and the type of insulating layer may be the materials applied to the first insulating layer. A thickness of the second insulating layer 24b may be 30 to 200 nm.

The gate foot 30b is formed to pass through the first and second insulating layers 24a and 24b. Here, the gate foot 30b may be in contact with the active layer 21, the cap layer 22, or the gate dielectric layer 31.

Further, the gate head 30a is extended in the direction of the drain, and is supported by the field plate 26 positioned thereunder. A metal for a gate electrode generally known in the art may be used as the metal for the gate electrode. For example, in a case where the field effect transistor is the HEMT device using a gallium nitride (GaN)-based compound semiconductor, a metal layer in which a nickel (Ni) layer having a thickness of 10 to 60 nm and a gold (Au) layer having a thickness of 200 to 500 nm are sequentially deposited may be used as the gate electrode 30. Further, in a case where the field effect transistor using a gallium arsenide (GaAs)-based compound semiconductor, such as the HEMT and the MESFET, a titanium (Ti) layer having a thickness of 20 to 50 nm, a platinum (Pt) layer having a thickness of 10 to 60 nm, and a gold (Au) layer having a thickness of 200 to 500 nm are stacked may be used as the gate electrode 30.

The field effect transistor having the aforementioned structure may be manufactured by performing a step of forming the first insulating layer 24a including the source and drain electrodes 23 on the active layer 21, forming the field plate 26 on the first insulating layer 24a, forming the second insulating layer 24b on the first insulating layer 24a on which the field plate 26 is formed, forming a micro opening by etching the first insulating layer 24a and the second insulating layer 24b, and forming the gate electrode 30 including the gate foot 30b formed in the micro opening and the gate head 30a extended in the direction of the drain to be supported by the field plate 26.

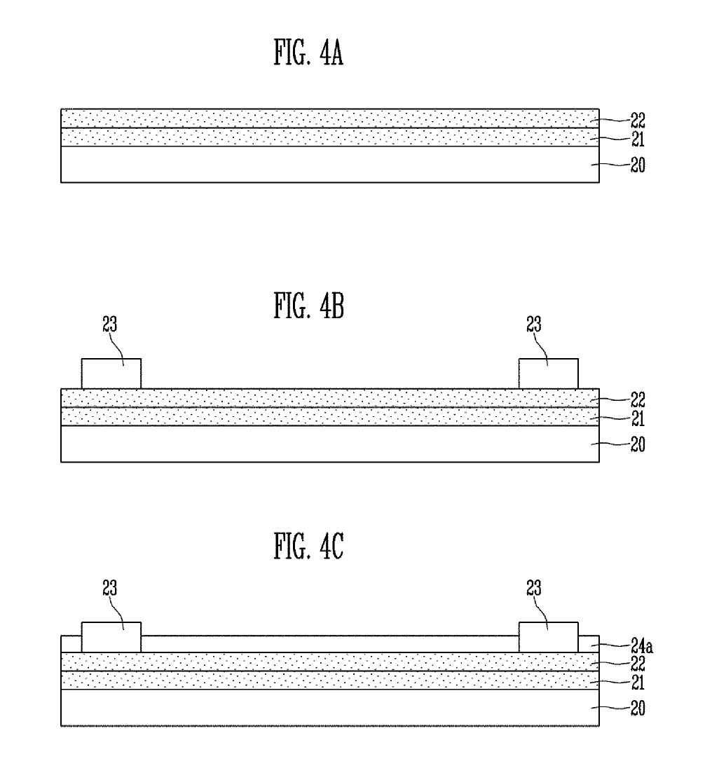

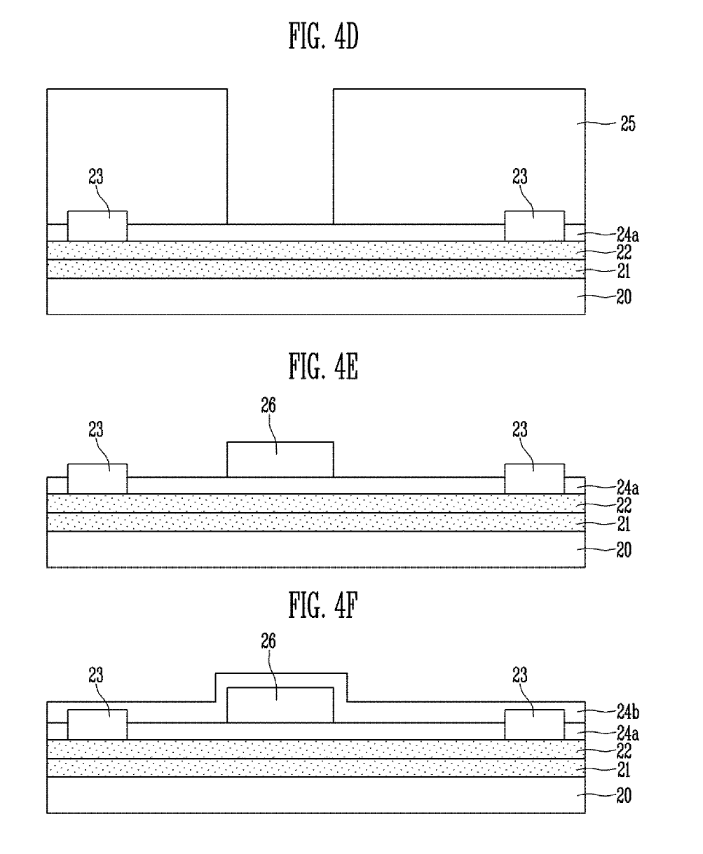

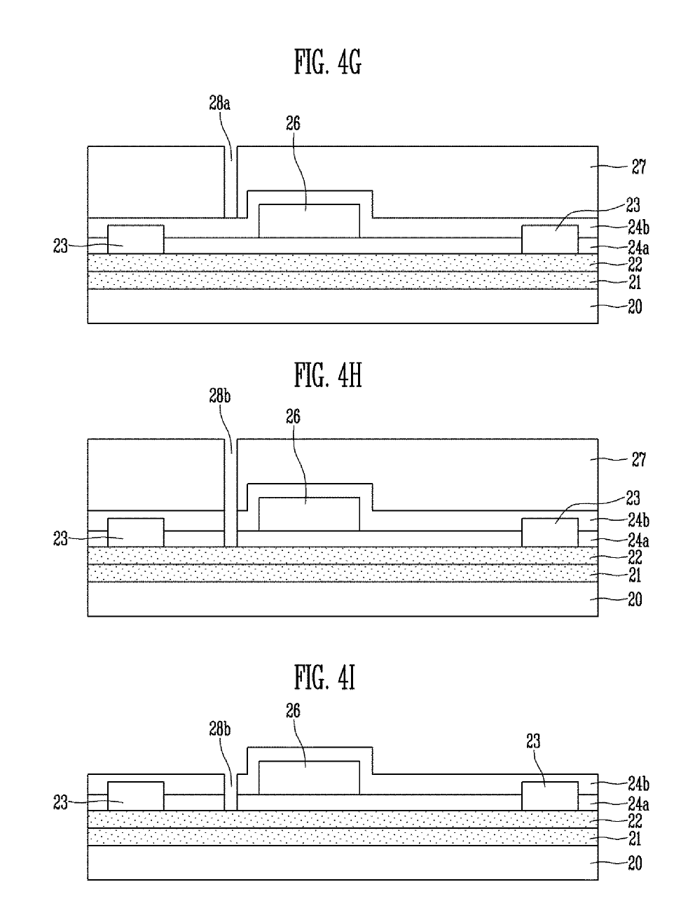

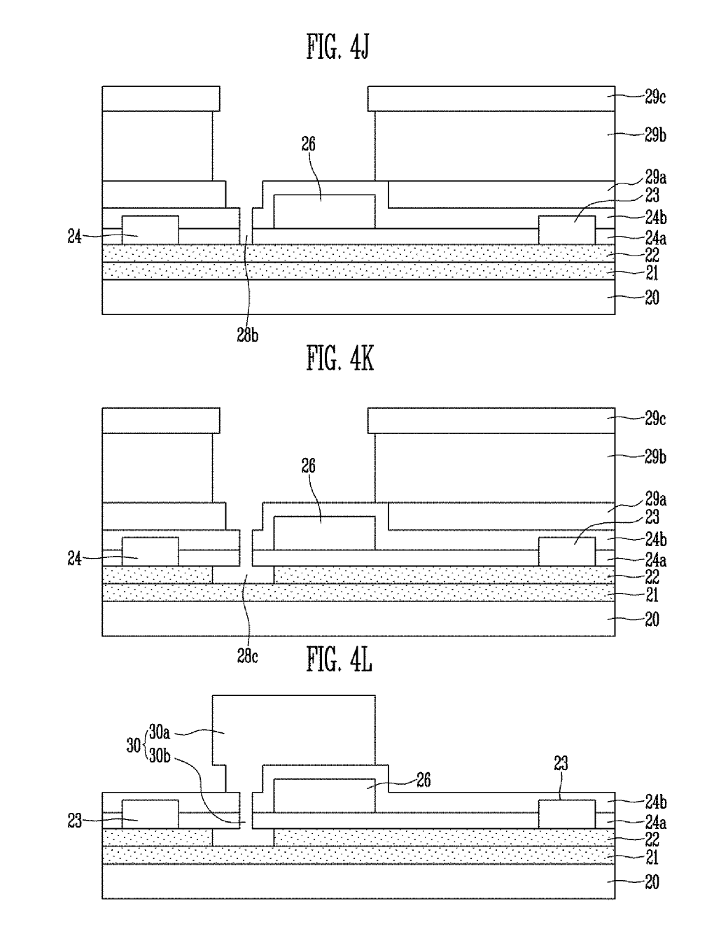

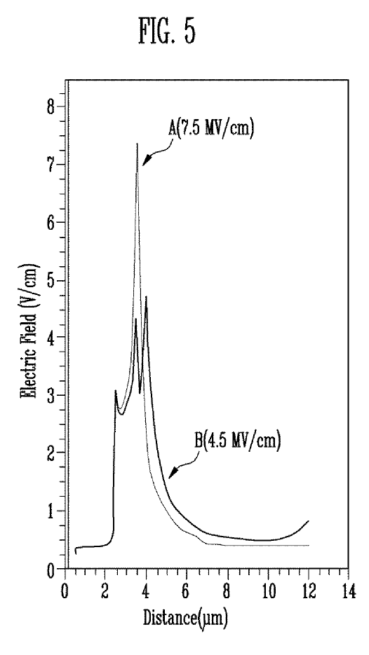

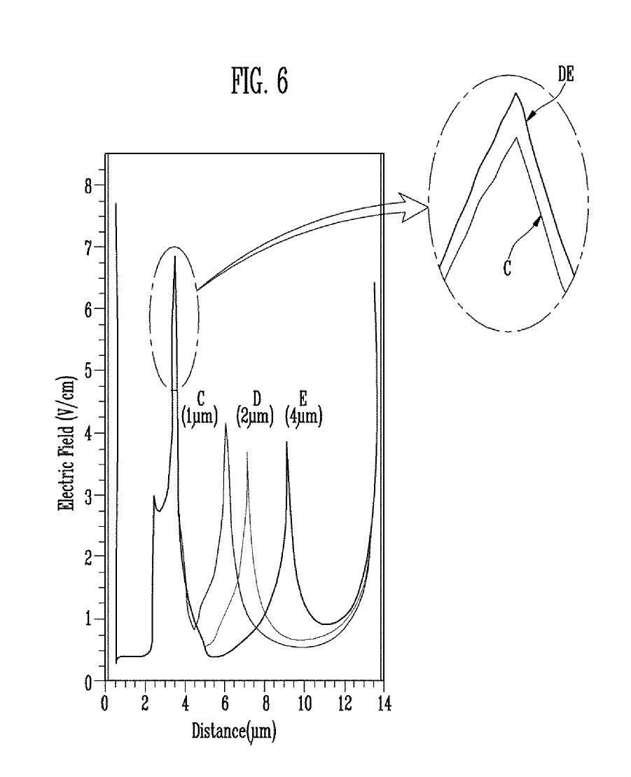

FIGS. 4A to 4L are process views illustrating a manufacturing process of the field effect transistor according to the exemplary embodiment of the present invention. Hereinafter, a method of manufacturing a field effect transistor including a gate electrode of which a gate head extended in a direction of a drain is supported by a field plate positioned thereunder will be described in more detail with reference to FIGS. 4A to 4L.

As illustrated in FIG. 4A, an active layer 21 and a cap layer 22 are formed on the semiconductor substrate 20. For reference, the step of forming the cap layer 22 may be omitted. Further, a gate dielectric layer 31 (see FIG. 3) may be formed on the cap layer 22. For example, the gate dielectric layer may be SiO₂, Si₃N₄, HfO₂, Al₂O₃, and ZnO.

As illustrated in FIG. 4B, a region in which source and drain electrodes are to be formed is defined by a photoresist pattern, ohmic metal for the source and drain electrodes is deposited, and then the source and drain electrodes 23 are formed by Rapid Thermal Annealing (RTA) and the like. Here, in a case where the field effect transistor is an HEMT device using a gallium nitride (GaN)-based compound semiconductor, a metal layer, in which Ti/Al/Ni/Au layers having predetermined thicknesses are sequentially deposited, may be used as the source and drain electrodes 23. Further, in a case where the field effect transistor is a device, such as an HEMT and an MESFET, using a gallium arsenide (GaAs)-based compound semiconductor, a metal layer, in which an AuGe layer, an Ni layer, and an Au layer having predetermined thicknesses are sequentially deposited, may be used as the source and drain electrodes 23.

Next, as illustrated in FIG. 4C, a first insulating layer 24a including the source and drain electrodes 23 is formed. For example, the first insulating layer 2a is formed so as to cover the source and drain electrodes 23, and then the first insulating layer 24a may be etched back so that upper portions of the source and drain electrodes 32 are exposed. Otherwise, the first insulating layer 24a may be formed before forming the source and drain electrodes 23.

Here, the first insulating layer 24a may be an insulating layer of a single layer or a multilayer, and may include materials, such as silicon nitride, silicon oxide, Al₂O₃, ZnO, HfO₂, BCB, and other porous silica thin layer.

Next, as illustrated in FIG. 4D, the source and drain electrodes 23 cover an upper portion of the first insulating layer 24a, and a photoresist pattern 25 having an opening is formed between the source and drain electrodes 23. Here, the opening is positioned in a region in which an electric field metal is to be formed. For example, the opening is positioned at a position at which a gate head is to be formed in a subsequent process. Further, development of the photoresist layer may be performed by a lithography process.

Next, as illustrated in FIG. 4E, after the field plate 26 is formed within the opening, the photoresist pattern 25 is removed by a lift-off process. For example, the metal layer for the field plate may be simultaneously deposited during performance of a process of depositing a device pad and a metal for transmission lines. Further, for example, a multilayered metal layer, such as titanium (Ti)/gold (Au) or nickel (Ni)/gold (Au), may be used as the metal for the field plate. The field plate 26 may be connected with a gate electrode or a source electrode.

In the meantime, after the photoresist pattern 25 is formed, a process of etching the first and second insulating layers 24a and 24b exposed through the opening by a predetermined thickness may be additionally performed. Accordingly, the thickness of the insulating layer under the field plate 26 may be adjusted. For example, the first and second insulating layers 24a and 24b may be etched by a dry etching process by using equipment of Reactive Ion Etching (RIE), Magnetically

Enhanced Reactive Ion Etching (MERIE), Inductive Coupled Plasma (ICP), and the like. In this case, the etching process may use CF₄ gas, mixture gas of CF₄ gas and CHF₃ gas, mixture gas of CF₄ gas and O₂ gas, and the like. Further, in a case where a wet etching process is applied, an etchant, such as a Buffered Oxide Etchant (BOE), may be used.

Next, as illustrated in FIG. 4F, the second insulating layer 24b of the single layer or the multilayer is deposited on the first insulating layer 24a on which the field plate 26 is formed. The type of second insulating layer 24b may be thin layer materials applied to the first insulating layer 24a.

Materials and thicknesses of the first and second insulating layers 24a and 24b may be determined considering an etch rate of the photoresist layer 27 forming the photoresist pattern used as an etching mask in the etching process of the insulating layer to be described below and etch rates of the insulating layers 24a and 24b.

As illustrated in FIG. 4G, the photoresist pattern 27 including a micro opening 28a exposing the second insulating layer 24b is formed on the second insulating layer 24b. Here, the purpose of the micro opening 28a is to define a region of the gate foot in a subsequent process, and is spaced apart from the field plate 26 by a predetermined interval. For example, the micro opening 28a spaced apart from the field plate 26 by 300 to 1,000 nm is formed by performing the lithography process on the photoresist layer coated on the second insulating layer 24b.

As illustrated in FIG. 4H, a micro opening 28b is extended in a downward direction by etching the first and second insulating layers 24a and 24b by using the photoresist pattern 27 as an etching mask. Here, the micro opening 28b may be formed to have a depth by which the cap layer 22 is exposed, a depth by which the active layer 21 is exposed, or a depth by which a predetermined thickness of the first insulating layer 24a is left. The etching process of the first and second insulating layers 24a and 24b is performed considering the materials and the thicknesses of the first and second insulating layers 24a and 24b, the etch rate of the photoresist pattern 27, and the etch rates of the first and second insulating layers 24a and 24b.

The etching process of the first and second insulating layers 24a and 24b may be performed by a dry etching process with equipment of RIE, MERIE, ICP, or the like. In this case, the etching process may be performed by using CF₄ gas, mixture gas of CF₄ gas and CHF₃ gas, mixture gas of CF₄ gas and O₂ gas, and the like.

For reference, in a case where the gate dielectric layer 31 (see FIG. 3) is formed on the cap layer 22, the micro opening 28b may be formed by a depth by which the gate dielectric layer is exposed. Further, the cap layer 22 or the active layer 21 is exposed through the micro opening, the photoresist pattern 27 is removed, and then the gate dielectric layer (not illustrated) may be deposited. For example, the gate dielectric layer may be SiO₂, Si₃N₄, HfO₂, Al₂O₃, and ZnO.

Subsequently, as illustrated in FIG. 4I, the photoresist pattern 27 is removed, and as illustrated in FIG. 4J, multilayered photoresist patterns 29a, 29b,and 29c are formed on the second insulating layer 24b. Here, the photoresist patterns 29a, 29b,and 29c includes the opening exposing a region in which the gate head extended toward the region of the drain is to be positioned. For example, after the multilayered photoresist layer, such as PMMA/copolymer/PMMA or ZEP/PMGI/ZEP, is formed, the photoresist layer is exposed by using electro-beam lithography and developed with a developing solution to form the photoresist patterns 29a, 29b, and 29c. When the photoresist patterns 29a, 29b, and 29c are formed by using the electro-beam lithography process as described above, the photoresist patterns 29a, 29b, and 29c for the gate electrode, in which the region of the gate head is larger than the region of the gate foot, may be manufactured. Accordingly, it is possible to form a T-shaped gate electrode of which a gate width may be decreased without an increase in resistance of the gate electrode.

Next, as illustrated in FIG. 4K, a gate recess region 28c is formed by performing a gate recess process of etching the cap layer 22 exposed through the opening of the photoresist patterns 29a, 29b, and 29c and the micro opening 28b or the cap layer 22 and a portion of the active layer 21. The gate recess process is the most important process step in a device, such as the HEMT and the MESFET, using a compound semiconductor. In general, the gate recess process is performed while measuring a current, and may be performed by a wet process or a dry process, or by a combination of a dry process and a web process. The gate recess process may be performed by using gas, such as CF₄, BCl₃, Cl₂, and SF₆ in dry etching equipment adopting an Electron Cyclotron Resonance (ECR) method and an Inductive Coupled Plasma (ICP) method. For example, when the field effect transistor is a GaAs-based compound semiconductor device, the gate recess process may be performed by using a wet etchant, such as a phosphoric acid-based solution in which H₃PO₄, H₂O₂, and H₂O are mixed at an appropriate ratio.

Further, the recess process may not be performed in the process of the device as necessary.

Finally, as illustrated in FIG. 4I, a gate electrode 30 is formed by forming a metal for the gate electrode in the opening of the gate recess region 28c, the micro opening 28b, and the photoresist patterns 29a, 29b, and 29c, and then removing the photoresist patterns 29a, 29b, and 29c by a lift-off process. Accordingly, the gate electrode 30 including a gate foot 30b passing through the first and second insulating layers 24a and 24b, and a gate head 30a extended in the direction of the drain and supported by the field plate 26 is formed.

Here, the gate foot 30b may be in contact with the active layer 21, the cap layer 22, or the gate dielectric layer according to the depth of the micro opening 28b or the formation or not of the gate recess region 28c. Further, the gate head 30a extended in the direction of the drain is supported by the field plate 26 positioned at a lower portion, and the gate head 30a and the field plate 26 is electrically insulated by the second insulating layer 24b. Accordingly, it is possible to manufacture the gate electrode 30 having a stable structure.

Further, resistance of the gate electrode 30 is decreased by extended the gate head 30a in the direction of the drain. In addition, an electric field peak value between the gate and the drain is decreased at an edge of the gate electrode 30 in the direction of the drain, thereby achieving an effect of an increase of a breakdown voltage of the device. In addition, a separate additional mask is not required while forming an field plate, thereby improving productivity, achieving a more uniform process than an existing process, and reproducibly manufacturing transistors having excellent performance

FIGS. 5 and 6 are graphs illustrating a characteristic of the field effect transistor according to the exemplary embodiment of the present invention.

In the present exemplary embodiment, a characteristic is measured by using the field effect transistor adopting a substrate structure in which a buffer layer, an intrinsic GaN layer (3 μm), AlGaN (25 nm, Al%=25%), and i-GaN (1.25 nm) are sequentially grown on a silicon substrate having a resistance value of 6000 Ω*cm. Here, the characteristic is analyzed under a condition that a length of the gate is 1 μm, a drain voltage is 400 V, and a gate voltage is a gate voltage in an off-state.

The graph of FIG. 5 represents an electric field distribution between the gate electrode and the drain electrode, an X-axis represents a distance (um) between the gate electrode and the drain electrode, and a Y-axis represents an electric field (V/cm). Further, in the present graph, “A” represents a case in which the gate head is not extended in the direction of the drain, and a peak value is 7.5 MV/cm. “B” represents a case in which the gate head is extended by 1 μm in the direction of the drain, and a peak value is 4.8 MV/cm. Referring to FIG. 4, it can be seen that the gate head is extended by 1 μm in the direction of the drain, so that the electric field peak value at the edge of the gate electrode in the direction of the drain is decreased by 2.7 MV/cm.

The graph of FIG. 6 represents an electric field distribution between the gate electrode and the drain electrode according to a spaced distance between the field plate and the gate electrode, an X-axis represents a distance (um) between the field plate and the gate electrode, and a Y-axis represents an electric field (V/cm). Further, the present graph represents electric field distribution difference between a case C where the distance between the field plate and the gate electrode is 1 μm, a case D where the distance between the field plate and the gate electrode is 2 μm, and a case E where the distance between the field plate and the gate electrode is 4 μm. Referring to FIG. 5, it can be seen that as the spaced distance between the field plate and the gate electrode is decreased from 4 μm to 1 μm, the electric field value is considerably decreased at the edge of the gate electrode in the direction of the drain.

It can be seen through FIGS. 5 and 6 that the electric field peak value is decreased at the edge of the gate electrode in the direction of the drain by extending the gate head in the direction of the drain, and thus an off-state breakdown voltage of the electric field transistor is improved.

As described above, the embodiment has been disclosed in the drawings and the specification. The specific terms used herein are for purposes of illustration, and do not limit the scope of the present invention defined in the claims. Accordingly, those skilled in the art will appreciate that various modifications and another equivalent example may be made without departing from the scope and spirit of the present disclosure. Therefore, the sole technical protection scope of the present invention will be defined by the technical spirit of the accompanying claims.

What is claimed is:

1. A field effect transistor, comprising:
an active layer;
a first insulating layer formed on the active layer;
source and drain electrodes which are in contact with the active layer while passing through the first insulating layer;
a field plate formed on the first insulating layer and positioned between the source and drain electrodes;
a second insulating layer formed on the first insulating layer so as to cover the source and drain electrodes and the field plate; and
a gate electrode including a gate foot passing through the first insulating layer and the second insulating layer, and a gate head formed on the second insulating layer and extended in a direction of the drain to be supported by the field plate.

2. The field effect transistor of claim 1, wherein the gate foot is in contact with the active layer.

3. The field effect transistor of claim 1, further comprising:
a cap layer interposed between the active layer and the first insulating layer, and being in contact with the gate foot.

4. The field effect transistor of claim 1, further comprising:
a gate dielectric layer interposed between the active layer and the first insulating layer, and being in contact with the gate foot.

5. The field effect transistor of claim 4, wherein the gate dielectric layer includes a silicon nitride layer, a silicon oxide layer, an Al₂O₃ layer, a ZnO layer, or an HfO₂ layer.

6. The field effect transistor of claim 1, wherein the field plate is connected with the gate electrode or the source and drain electrodes.

7. The field effect transistor of claim 1, wherein the first insulating layer or the second insulating layer includes a silicon nitride, a silicon oxide, Al₂O₃, ZnO, HfO₂, benzocyclobutene (BCB), or porous silica thin layer.

8. A method of manufacturing a field effect transistor, comprising:
forming a first insulating layer and source and drain electrodes on an active layer, wherein the source and drain electrodes are in contact with the active layer while passing through the first insulating layer,;
forming a field plate on the first insulating layer;
forming a second insulating layer on the first insulating layer on which the field plate is formed;
forming a micro opening by etching the first insulating layer and the second insulating layer; and
forming a gate electrode including a gate foot formed in the micro opening and a gate head formed on the second insulating layer, extended in a direction of the drain, and supported by the field plate.

9. The method of claim 8, wherein the first insulating layer is formed before or after the source and drain electrodes are formed.

10. The method of claim 8, further comprising:
forming a cap layer on the active layer.

11. The method of claim 10, wherein the forming of the gate electrode includes:
forming a gate recess region by etching the cap layer or the active layer which is exposed through the micro opening;
forming a multilayered photoresist pattern including an opening on the first and second insulating layers in which the micro opening is formed, wherein the opening is formed at a region, in which the gate head is to be formed; and
forming the gate electrode including the gate foot which is in contact with the cap layer or the active layer.

12. The method of claim 11, wherein the forming of the gate recess region is performed by using CF₄ gas, BCl₃ gas, Cl₂ gas, or SF₆ gas in dry etching equipment adopting an Electron Cyclotron Resonance (ECR) method and an Inductive Coupled Plasma (ICP) method.

13. The method of claim 11, wherein the forming of the gate recess region is performed by using a phosphoric acid solution, in which H₃PO₄, H₂O₂, and H₂O are mixed, as a wet etchant.

14. The method of claim 10, further comprising:
forming a gate dielectric layer on the cap layer.

15. The method of claim 14, wherein the forming of the gate electrode includes the forming of the gate electrode including the gate foot which is in contact with the gate dielectric layer exposed through the micro opening.

16. The method of claim 8, wherein the forming of the field plate includes:
forming a photoresist pattern including an opening in a region, in which the field plate is to be formed, on the first insulating layer;
etching the first insulating layer exposed through the opening of the photoresist pattern by a predetermined thickness; and
forming the field plate in the opening.

17. The method of claim 8, wherein the forming of the field plate is simultaneously performed with a process of depositing a device pad and a metal for transmission lines.

18. The method of claim 8, wherein in the forming of the micro opening, the micro opening is formed by a depth at which the active layer is exposed, or by a depth at which the first insulating layer is left by a predetermined thickness.

19. The method of claim 8, wherein the forming of the micro opening is performed by an equipment adopting a Reactive Ion Etching (RIE) method, a Magnetically Enhanced Reactive Ion Etching (MERIE) method, or an Inductive coupled plasma (ICP) method.

20. The method of claim 8, wherein the forming of the micro opening is performed by using CF₄ gas, mixture gas of CF₄ gas and CHF₃ gas, or mixture gas of CF₄ gas and O₂.
